(19) United States
(12) Patent Application Publication
(10) Pub. No.: US 2006/0249724 A1
(43) Pub. Date: Nov. 9, 2006

(54) Method and structure for Peltier-controlled phase change memory

(75) Inventors: Lia Krusin-Elbaum, Dobbs Ferry, NY (US); Dennis M. Newns, Yorktown Heights, NY (US)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: International Business Machines Corporation, Armonk, NY (US)

(21) Appl. No.: 11/123,086

(22) Filed: May 6, 2005

(51) Int. Cl. H01L 29/02

(52) U.S. Cl. 257/2

(57) ABSTRACT

A memory cell includes a phase change material (PCM) element that stores an information bit. A heating element external to the PCM element changes the information bit. A cooling element increases the speed of the information bit change.

### BACKGROUND OF THE INVENTION

1. Field of the Invention

The present invention generally relates to a memory or storage unit, and specifically to a non-volatile memory or storage unit. More specifically, Peltier elements provide both heating and cooling for a phase change material (PCM) element to greatly improve speed and controllability when only a thin layer of the PCM is used for storing the information state of the memory unit.

2. Description of the Related Art

The most widely used form of memory, dynamic random access memory (DRAM), has a number of well-known disadvantages. First, the memory is volatile, meaning that it is lost when the computer or device is switched off. Second, it is relatively slow. Third, it would be desirable to significantly reduce the memory “footprint” (e.g., the physical size of the memory unit).

These drawbacks have led to interest in a proposed new type of nonvolatile memory, phase change memory, or PRAM.

Phase change materials (PCM), which can coexist in either a crystalline or amorphous phase state, are currently the basis of commercial optical CD-RW disk technology, as well as the newly-proposed PRAM. In CD-RW, bit-spots on the disk may be in either of two phase states. Thermal cycling, done by extrinsic laser heating, interconverts the two states 100, as shown in FIG. 1. Amorphous-to-crystalline conversion involves an anneal below melting point (“Set” process), while crystalline-to-amorphous conversion involves melting followed by a fast quench (“Reset” process). Spots are read by exploiting the different optical reflectivity of the two phases.

All current PRAM designs (termed here “conventional”) have evolved from a concept based on ternary PCM compositions GeSbTe (germanium antimony tellurium), commonly abbreviated GST, having a highly resistive amorphous state and a low resistance crystalline state. A commonly-used GST is Ge₂Sb₂Te₅ (hereinafter, referred to as “GST 225”).

To convert from the conductive to the resistive state, current is passed through the PCM, melting it via internal joule heating, followed by a quench to the resistive state. Converting from the resistive to the conductive state involves first driving the PCM to electrical breakdown, then passing current to anneal to the conductive state. The Read process exploits the different electrical resistivities of the two states, which are easily distinguished.

However, because the electrical breakdown process is non-linear and not easily controlled, there remains a need to improve PRAM designs. Moreover, current PRAM is too slow to compete effectively with DRAM.

Additionally, in view of the disadvantages identified above for DRAM, an improvement in PRAM design would ideally additionally address one or more of these disadvantages, thereby allowing PRAM to successfully compete with DRAM in at least some applications.

### SUMMARY OF THE INVENTION

In view of the foregoing, and other, exemplary problems, drawbacks, and disadvantages of the conventional system, it is an exemplary feature of the present invention to provide an improved PRAM memory cell.

It is another exemplary feature of the present invention to provide a technique in which information can be more rapidly placed (e.g., stored) into a PRAM memory cell by providing a cooling element for more rapid transition from a heating cycle used for placing (e.g., storing) information in the cell.

To achieve the above exemplary features and others, in a first exemplary aspect of the present invention, described herein is a memory cell, including a phase change material (PCM) element that stores an information bit, a heating element external to the PCM element to change the information bit, and a cooling element to increase a speed of changing the information bit.

In a second exemplary aspect of the present invention, also described herein is an apparatus, including a non-volatile memory array. The non-volatile memory array includes a plurality of memory cells arranged in an array of rows and columns, a word line for each row, the word line being connected to each memory cell in the row, a bit line for each column, the bit line being connected to each memory cell in the column, and a sense amplifier in each bit line. At least one of the memory cells includes a phase change material (PCM) element and a heating/cooling element external to the PCM element.

In a third exemplary aspect of the present invention, also described herein is a method of increasing speed in a phase change material PCM random access memory (PRAM), including providing a cooling element to expedite a cooling process after the PCM material has been heated to change an information bit in a PRAM memory cell.

In a fourth exemplary aspect of the present invention, also described herein is a method of forming a non-volatile memory cell, including forming a heating/cooling element on a substrate and forming a portion of phase change material (PCM) in close proximity to the heating/cooling element.

In a fifth exemplary aspect of the present invention, also described herein is a memory cell, including a phase change material (PCM) element that stores an information bit and a Peltier device located in close proximity to a surface of the PCM element. The Peltier device serves to selectively heat/cool the surface of the PCM element. The information bit is stored in the PCM element within a PCM layer adjacent to the surface closest to the Peltier device, and the thickness of the PCM layer storing the information bit is in the nanoscopic range.

Thus, the present invention provides an improved PRAM memory cell wherein a cooling element increases a switching speed for establishing an information bit by reducing the amount of time for converting between amorphous and crystalline states, thereby providing improved performance, speed, and size over conventional PRAM devices and presents an advantageous new technology that is very promising as a storage class memory.

Moreover, a high performance PRAM, such as taught by the present invention, is suitable as a local nonvolatile memory embedded in the logic chip environment. In this application, following a run interruption, the exact logic state of the system can be restored, enabling seamless continuation of the interrupted task, an advantage not provided by DRAM.

A second application is in hand-held devices, such as portable computers (e.g., such as laptop computers), cell phones, portable audio and/or video devices, or the like, where the nonvolatile and high density properties of PRAM enable it to replace a compact disk, thereby enhancing additional miniaturization of these types of devices for which compactness is highly desired by consumers.

### BRIEF DESCRIPTION OF THE DRAWINGS

The foregoing and other exemplary features, aspects and advantages will be better understood from the following detailed description of an exemplary embodiment of the invention with reference to the drawings, in which:

FIG. 1 illustrates the thermal cycling 100 for the set and reset processes of a phase change material, as might be used in conventional optical CD-RW disk technology;

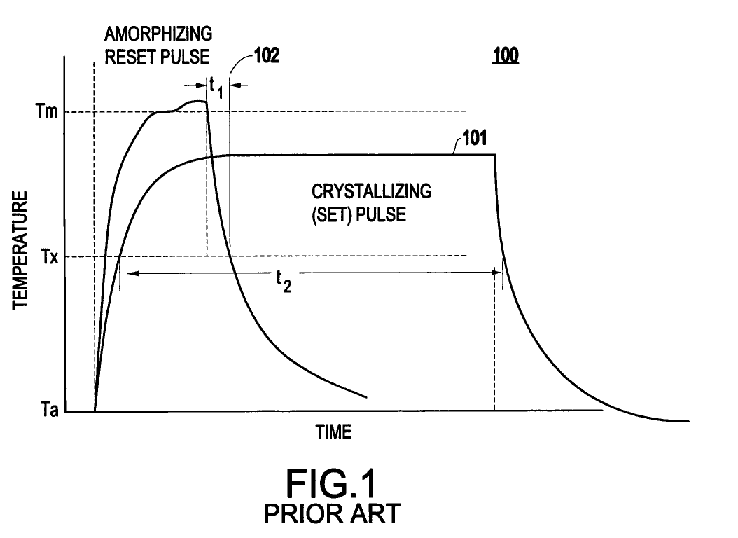

FIG. 2 exemplarily illustrates a cross section of a structure 200 of an exemplary embodiment of the present invention;

FIG. 3 illustrates an exemplary memory cell configuration 300 using a Peltier heater/cooler and an FET switch;

FIG. 4 illustrates cooling cycle curve 400 at 5 nm depth within the GST element; and

FIG. 5 exemplarily illustrates a 3×3 memory array 500 using Peltier heater/cooler elements.

### DETAILED DESCRIPTION OF EXEMPLARY EMBODIMENTS OF THE INVENTION

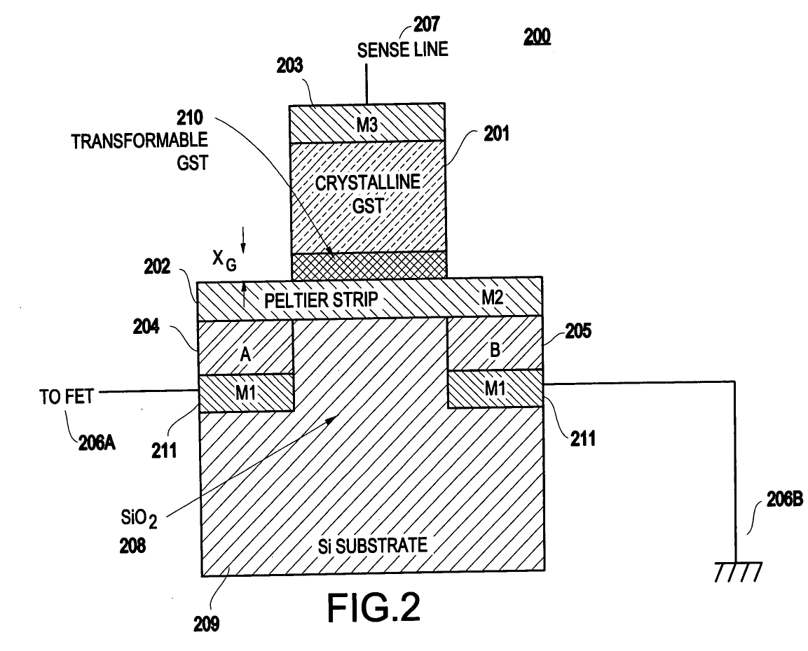

Referring now to the drawings, and more particularly to FIGS. 2-5, exemplary embodiments of the present invention will now be described.

PRAM based on new material compositions are currently being investigated, such as binary GeSb, having two orders of magnitude lower resistivity in both states (e.g., amorphous and crystalline). However, these new compositions are not suitable for the internal joule heating/electrical breakdown scenario, because the low resistance of the PCM in the crystalline state requires inconveniently high currents for convenient internal joule heating, while the amorphous state is too conductive for electrical breakdown.

Heating by an external element, whose properties are independent of the PCM state, offers a clean solution for these materials, bringing the PRAM closer in concept to the CD-RW. Moreover, there are advantages in terms of reproducibility and analyzability, including understanding of scaling, for applying the external heater solution also to the ternary PCM materials.

A first co-pending application, U.S. patent application Ser. No. 10/401,564, filed on Mar. 31, 2003, to Hendrik F. Hamann et al., entitled “THERMAL MEMORY CELL AND MEMORY DEVICE INCLUDING THE THERMAL MEMORY CELL”, having IBM Docket YOR920020277US1, demonstrated one configuration of an external heater in PRAM.

A second co-pending application, U.S. patent application No. 10/______, filed on ______, to Krusin-Elbaum et al., entitled “METHOD AND STRUCTURE FOR HIGH PERFORMANCE PHASE CHANGE MEMORY,” having IBM Docket YOR920050036US1, provides an extension to this basic concept of using an external heater for PRAM by describing how using only a thin PCM layer in close proximity to the external heater for the information storage of the memory cell allows the switching speed to be dramatically improved for PRAM devices.

Thus, it is noted that one of ordinary skill in the art, after having read the details described herein and the first and second of the three above-identified co-pending applications, would readily be able to recognize how the present invention is related. More specifically, as mentioned above, the first of these three co-pending applications introduced an external heater concept to PRAM. The second co-pending application introduced the concept of using only a very thin surface layer of the PCM element for storing the information bit of the memory cell, in the neighborhood of 5-10 nanometers or less.

The present invention can be considered as a specialized and non-obvious embodiment of the second co-pending application that adds the capability of cooling to a thin-layer PCM having an external heating element.

Additionally, more specific to the present invention, the present inventors have also recognized that greater controllability of the phase change process, with the promise of higher speed, could be assured if, in addition to heating, cooling could also be provided by an external element, so as to enhance the quench (Reset) process. Operability in a regime of faster crystallization would then be possible, speeding up also the anneal (Set) process.

This recognition suggested to the present inventors the possibility of extending the concept of an external heater to the concept of an external heater/cooler as embodied in a Peltier heater/cooler device.

The present invention, therefore, presents a novel PRAM memory cell wherein phase change is controlled by both the heating capability and the cooling capability of Peltier heater/cooler elements that are external to the PCM. Thus, the Peltier heater/cooler elements accomplish the Set and Reset processes by appropriate thermal cycling, utilizing both heating and cooling capabilities.

Because of its external heater element, in the present invention, current flows through the PCM element only during the read process, when the information content of the memory cell is determined by determining the resistivity of the PCM element. In the design of the present invention, in which a Peltier device serves as an external heater for the PCM element, current flows through the Peltier device in one sense to provide heat for the Set state of the PCM element and the initial stage of the Reset, but the current sense is reversed in the quench stage of Reset to provide cooling for the PCM element, hence speeding up the quench.

A second key aspect of the present invention is the use of small dimensions, which critically relate to speed of the device. That is, by incorporating film thicknesses, the present invention is highly controllable to small dimensions, including dimensions directly related to improving the speed of operation.

Thus, because of the external heater and the thin layers used, the exemplary design discussed herein provides a number of advantages, including:
Reproducibility due to the absence of nonlinear electrical breakdown processes;
Analyzability due to ohmic conduction and simple geometry;
Applicability to a wide range of PCM compositions, since the thermal cycling is independent of PCM resistivity;
High degree of control over the phase change process due to independent control of both heating and cooling processes;
Heating power is linear in current, providing more power at low currents; and
The key small dimensions of the device, which critically relate to speed, are thin film thicknesses, and, thus, easily fabricated precisely to low values.
   Description and Function of a Single Cell

An exemplary memory cell configuration 200 of the present invention includes a GST element 201 sandwiched between two metal electrodes 202, 203, as shown in FIG. 2. One electrode 202, termed the “Peltier strip”, which connects two thermoelectric materials, A 204 (with a positive thermopower) and B 205 (with a negative thermopower), constitutes an external Peltier heater/cooler for the GST element 201.

The Peltier electrode A is connected to the FET switch drain 206A, while the B electrode is grounded 206B. The other electrode 203 attached to the GST element 201 is connected to a sense line 207.

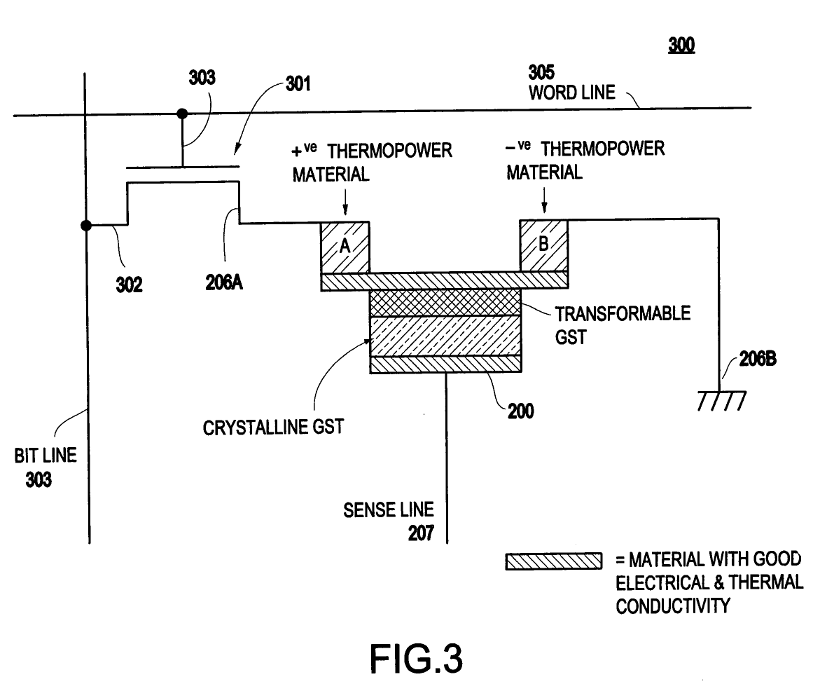

The device 200 is exemplarily shown in FIG. 2 as constructed on top of an SiO₂ layer 208 on a silicon substrate 209. However, other insulators (oxides or nitrides) may be used as long a the thermal path discussed below is not compromised. Although not shown in FIG. 2, the memory cell configuration 300 exemplarily illustrated in FIG. 3 shows that the source 302 of FET 301 is connected to the bit line 303, while the gate 304 is connected to the word line 305.

Functionality in PRAM involves three processes, including the two “write” processes Set and Reset, and a Sense (e.g., “read”) process. All functions involve enabling a particular Word line 305 via the FET gate.

The Reset step melts a thin layer 210 of GST close to the Peltier electrode 202, named “transformable GST” in FIG. 2. This melting is implemented by a current flowing from A to B (e.g., from the FET 206A and bit line 303), followed by a fast quench to a high-resistance amorphous state. The quenching is implemented by a reversed current, flowing from B to A (e.g., into the FET 206A and bit line 303), which achieves Peltier cooling of the transformable GST layer 210. During this process the Sense line is open circuited, thereby ensuring that no current flows through the GST material 201.

The Set step involves an anneal of the amorphous transformable GST layer 210 to a low-resistance crystalline state, which is achieved by Peltier heating (current flowing from A to B) to a lower temperature than required for melting, but for a longer time. Again, during this process the Sense line 207 is open circuited so that no current flows through the transformable GST layer 210.

The sense step involves determining the amorphous or crystalline state of the transformable GST layer 210 by interrogating its electric resistance with a sense amplifier, using the bit line 303 as a voltage source. During this process, the Sense line 207 is in the circuit.

Physical Implementation and Materials Aspects

FIG. 2 shows an exemplary physical implementation of a memory section of a cell. A thermally and electrically insulating layer 208, such as SiO₂, is deposited on the silicon substrate 209, with a thickness of approximately 200-400 nm. This layer is patterned so as to obtain trenches into which the contact metal layer M1 (e.g., metal layer 1) 211 is deposited, followed by the deposition of the thermoelectric elements A and B 204, 205 (film thickness of approximately 100-200 nm) to form the Peltier heater/cooler assembly. After planarization of this layer, a metal layer M2, forming the Peltier strip 202, is patterned to contact elements A and B. The thickness of the M2 layer is approximately 10 nm., and one choice of material is TiN.

Preferably, the choice of the thermoelectric materials A and B is based on:

1. The materials preferably should have a high Peltier coefficient (positive for A, negative for B);

2. The thermoelectric efficiency factor, defined as

$$ZT = \frac{{Π}^{2} σ}{κ T} ,$$

where Π is the Peltier coefficient, σ is the electrical conductivity, and κ is the thermal conductivity, of the A or B elements preferably should be of order unity or larger; and

3. The material preferably maintains this high thermoelectric efficiency up to the melting temperature of the GST.

Possible materials that satisfy these conditions include:

1. For material A, alkaline earth filled skutterudites, with the composition AT₄Sb₁₂, where A=Ca, Sr, Ba; and T=Fe, Ru. Additional choices are the skutterudites IrSb₃, HfTe₅, ZrTe₅. A further choice is AT₄X₁₂, where composition materials involve A=La, Ce, Pr, Ne or Eu; T=Fe, Ru, or Os; and X=P, As, or Sb.

2. For material B, one choice is the half-Heusler alloys MNiSn, where M=Zn, Hf, Ti. These materials have huge negative thermopowers, good thermoelectric efficiency factor ZT, and operate at 700K. Moreover, their properties are tunable by doping. Another recent class of materials are cubic chalcogenides, with composition AgPbₘSbTe₂₊ₘ. These latter materials may be particularly compatible with the processing of GST elements.

The next step is the deposition of LTO, which is subsequently patterned with vias down to M2 (e.g., metal layer # 2) level, that are filled with the GST (approx. thickness 15 nm). The final electrical contact 203 is an M3 metal layer made to the top of the GST element 201. M2 and/or M3 can be high K material, such as W or TaN.

Technical Estimates of Cell Performance

The analysis of the exemplary configuration shown in FIGS. 2 and 3 assumes that the principal heat loss is through the oxide 208, due to its significantly larger specific heat-thermal conductivity product relative to that of GST 201. Hence, a one-dimensional analysis, in which heat propagation is normal to the plane of the Peltier heating/cooling element, can be used. Heat loss from the Peltier strip through the thermoelectric materials A and B, which characteristically have low thermal conductivities similar to SiO₂, will be similar to that through the oxide.

First, the materials parameters shown in Table I are considered. For definiteness, a GST material with the properties approximating those of the well-studied 225 material Ge₂Sb₂Te₅ is considered. The oxide parameters are those of SiO₂.

TABLE I
Specific Heat Cₚ, Thermal Conductivity
K, electrical conductivity σ

| | GST | GST | | |
|---|---|---|---|---|
| Phase | Cryst. | Amorph. | Oxide | Si |
| Cₚ(J/(Kcm³) | 1.3 | 1.3 | 3⁺⁺ | 1.6 |
| K(J/(Kcmsec))* | 0.005 | 0.0017 | 0.013⁺⁺ | 0.8⁺ |
| σ (Ohm⁻¹cm⁻¹) | 100** | 0.001 | — | |

*Dependent on source
**Controllable by N-doping.
⁺Average over
⁺⁺Typ.

The model is then a single-sided 1D model, in which temperature is considered as a function of x and time t. Assuming excellent thermal conductivity of the Peltier strip, the temperature is considered to be uniform, with value Tₚ(t), within the strip. The temperature distribution within the oxide is denoted as Φₒₓ(x,t).

Within the oxide, the diffusion equation applies:

$$\frac{\partial {Φ}_{ox}}{\partial t} = {D}_{ox} \frac{{\partial }^{2} {Φ}_{ox}}{\partial {x}^{2}} ;$$

$${D}_{ox} = \frac{{K}_{ox}}{{C}_{ox}} ,$$

where Kₒₓ, Cₒₓ are the oxide thermal conductivity and volumetric specific heat, respectively. The diffusion equation is solved using Laplace transform techniques, and the results are stated in the asymptotic long-time limit which ignores the fast transients associated with thermal equilibration of the Peltier strip. The temperature T_{P} in the Peltier strip can be written in terms of a function ƒ_{P}(t)

$${f}_{P} ≃ \frac{2}{\sqrt{π {K}_{ox} {C}_{ox}}} {t}^{1 / 2} ,$$

in terms of which

$${T}_{P} = \frac{{W}_{H}}{A} {f}_{P} ( t ) - \frac{( {W}_{H} + {W}_{C} )}{A} {f}_{P} ( t - {t}_{S} ) θ ( t - {t}_{S} ) .$$

Here, W_{H}/A is the input heating power per unit area, W_{C}/A is the input cooling power per unit area, and A is the area. t_{S} is the time at which the heating cycle is replaced by a cooling cycle during reset. θ(t) is the step function.

Given the temperature evolution in the Peltier strip, the temperature profile inside the GST can be determined as follows, using the function g(x,t)
g(x,t)=ƒ_{P}(t)[e⁻²^{²}−z\sqrt{π}(1−erƒ(z))],
where z=x/\sqrt{4D_{G}t}, D_{G}=K_{G}/C_{G} is the diffusion constant for GST, K_{G} is the GST phase-averaged thermal conductivity, and C_{G} is the GST specific heat. With this, the temperature profile T_{G}(x,t) in the GST is given by

$${T}_{G} ( x , t ) = \frac{{W}_{H}}{A} g ( x , t ) - \frac{( {W}_{H} + {W}_{C} )}{A} g ( x , t - {t}_{S} ) θ ( t - {t}_{S} ) .$$

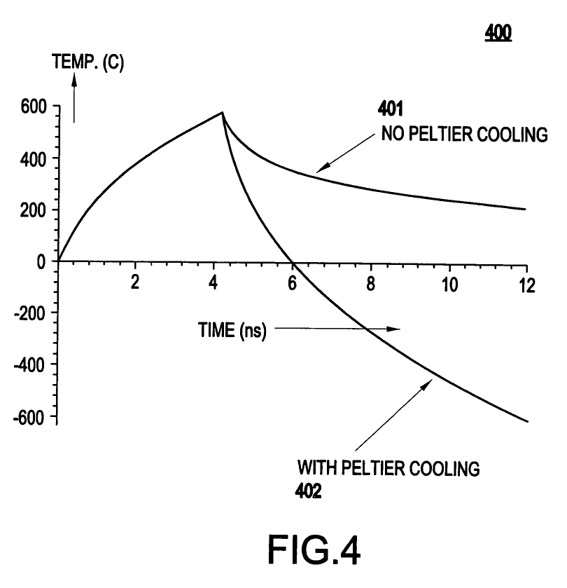

FIG. 4 illustrates a graph 400 of the time evolution of temperature T_{G}(x,t) within GST at a distance x=x_{G}=5 nm inside the surface, both without Peltier cooling 401 (W_{C}=0), and with Peltier cooling 402 (W_{C}=W_{H}). The parameters are collected below

TABLE II
Parameters

| x_{G}(nm) | I(mA) | S_{A} − S_{B}(μV/K) | A(nm²) | t_{S}(ns) |
|---|---|---|---|---|
| 5 | 0.167 | 300 | 50 × 50 | 4.2 |

From FIG. 4, it is seen that the Peltier cooling strongly enhances quench rate, as compared to just turning off the heating cycle.

The latent heat of crystallization, 420 Jcm⁻³ for the 225 GST material, absorbs approximately ½ as much heat as required to raise the material from room temperature to the melting point, an effect which should be taken into account in the heat balance, but it introduces a nonlinear effect which is more difficult to treat analytically than the simple heat diffusion. Neglect of latent heat thus limits accuracy to an order of a factor of two.

The Set process time scale depends on the time for the crystallization front to travel from the interface between the amorphous and crystalline phases to the surface at the Peltier strip. With x_{G}=5 nm and crystallization front velocity ν_{cryst}=2 m/sec, this would require 2.5 ns. However, the crystallization front velocity depends critically on temperature, so the lower the anneal temperature, the slower the Set process. The temperature dependence in the anneal process, and the latent heat should be taken into account.

The Sense process depends on the relatively large difference in resistivity between the amorphous and crystalline GST phases. When sense current is applied through the FET drain, the current×resistance of B acts as a voltage source driving current through the GST into the sense amplifier. With an electrical conductivity of σ=100 Ohm⁻¹cm⁻¹ (Table I), the 225 crystalline material in a thickness of 15 nm has a resistance of 600 Ω, while with the thin (5 nm.) layer of amorphous GST in series, the resistance would be orders of magnitude higher. These numbers depend sensitively on the GST composition, dimensions, etc., and preferably are tailored accordingly.

Memory Array

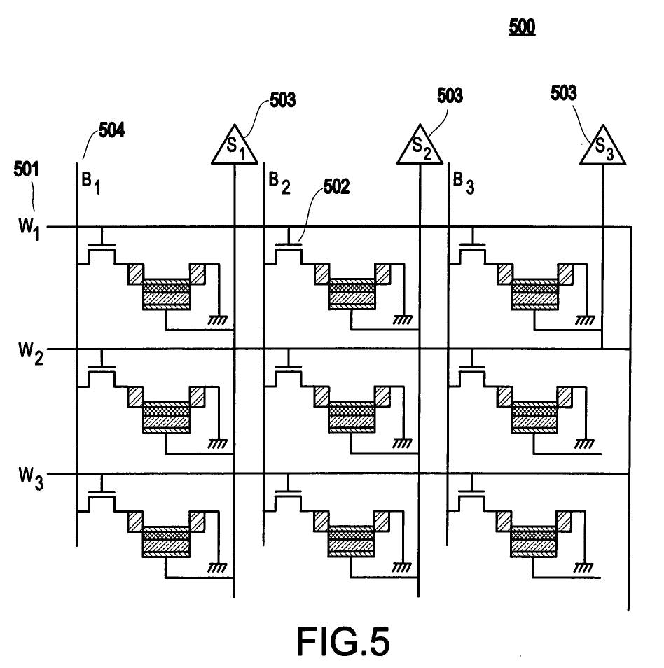

A 3×3 memory 500 is exemplarily illustrated in FIG. 5. Enabling a word line 501 is required for write and read processes. The FET switches 502 in that row are then turned on. For Set and Reset, the sense amplifiers 503 are open circuited, and current of appropriate directionality applied from the bitline 504.

For Sense, current is again applied from the bitline 504, now with the sense amplifiers 503 in the circuit. The sense amplifiers 503 detect a significant current only if the GST element is in the crystalline state. Typical block size of a memory, in practice, is 1024×1024 units of memory, rather than the 3×3 memory 500 shown in FIG. 5.

RC Time Constant, Memory Bandwidth

To calculate a time constant, the block physical dimension is estimated as 0.7×10⁻² cm. At an estimated 2 pF/cm lead capacitance per unit length, lead capacitance is on the order of 1.4×10⁻¹⁴ F. Hence, for currents of 0.2 mA to charge to 1 V, the time constant is 0.7×1⁻¹⁰ sec. This time constant is short enough so that the RC delay does not significantly affect circuit operation.

For Sense, the RC time constant leads to a delay of the order 0.8×10⁻¹⁰ sec, which however is also insignificant.

The time delays from the ancillary circuitry (code/decode, etc.) are similar to that for DRAM, i.e., relatively long.

A 3-nsec write time yields a memory bandwidth, assuming a 1024-bit word line, in simultaneous read/write mode, interfacing with a 64-bit channel, of ˜5 GHz.

Thermal Budget

For an applied voltage V, the heat for a single write step is estimated as, where τ is write time,
H_{wt}=VIτ≈0.7×10⁻¹²J,
where it is taken that V=1V and τ=4 ns. Now a 3 GHz computer outputting 64 b/cycle to memory, i.e. 2×10¹¹ b/sec, will therefore require a maximum 130 mW of power for writing to memory. Even this maximal estimate is quite low. The power requirement for a read is similar.

The power requirement of the ancillary circuitry (code/decode, etc.) is similar to that for DRAM.

The high performance PRAM of the present invention is suitable as a local nonvolatile memory embedded in the logic chip environment. In this application, following a run interruption the exact logic state of the system can be restored, thereby enabling seamless continuation of the interrupted task. A second application is in hand-held devices, where the nonvolatile and high density properties of PRAM enable it to replace the compact disk (CD), enhancing miniaturization.

While the invention has been described in terms of exemplary embodiments, those skilled in the art will recognize that the invention can be practiced with modification within the spirit and scope of the appended claims.

Further, it is noted that Applicants' intent is to encompass equivalents of all claim elements, even if amended later during prosecution.

Having thus described our invention, what we claim as new and desire to secure by Letters Patent is as follows:

1. A memory cell, comprising:
a phase change material (PCM) element for storing an information bit;
a heating element external to said PCM element for changing said information bit; and
a cooling element to increase a speed of changing said information bit.

2. The memory cell of claim 1, wherein said PCM element comprises a layer of said PCM and an information state of said memory cell is determined by a structure state of a portion of said phase change material a predetermined distance from said heating element, said structure state comprising one of an amorphous state of said PCM and a crystalline state of said PCM.

3. The memory cell of claim 1, wherein said PCM comprises a chalcogenide glass.

4. The memory cell of claim 1, wherein said PCM comprises one of:
a ternary germanium antimony tellurium (GeSbTe or GST) composition; and
a binary germanium antimony (GeSb) composition.

5. The memory cell of claim 2, wherein said portion comprises a thin layer, said thin layer comprising a layer of said PCM having thickness approximately 5-10 nm or less.

6. The memory cell of claim 1, wherein said PCM layer comprises a thin film on a chip.

7. The memory cell of claim 1, wherein said heating element comprises:
a Peltier strip; and
an electrode having a positive thermopower characteristic.

8. The memory cell of claim 1, wherein said cooling element comprises:
a Peltier strip; and
an electrode having a negative thermopower characteristic.

9. The memory cell of claim 1, wherein said PCM element directly contacts at least one of said heating element and said cooling element.

10. The memory cell of claim 1, wherein at least one of said heating element and said cooling element is embedded in a thermally insulative layer.

11. The memory cell of claim 1, further comprising:
a switching element to control application of a voltage to said memory cell.

12. The memory cell of claim 1, wherein said memory cell comprises one of a plurality of such memory cells arranged in an array of rows and columns to form a memory array, said memory array further comprising:
a word line for each said row, said word line connected to each memory cell in said row;
a bit line for each column, said bit line connected to each memory cell in said column; and
a sense amplifier in each said bit line.

13. The memory cell of claim 4, wherein said GST composition comprises Ge₂Sb₂Te₅ (GST 225).

14. The memory cell of claim 7, wherein said Peltier strip comprises TiN.

15. The memory cell of claim 7, wherein said electrode having said positive thermopower characteristic comprises one of:
an alkaline earth filled skutterudite, having a composition AT₄Sb₁₂, where A=Ca, Sr, or Ba, and T=Fe or Ru;
a skutterudite IrSb₃, HfTe₅, or ZrTe₅; and
a composition AT₄X₁₂ where A=La, Ce, Pr, Ne or Eu, T=Fe, Ru, or Os, and X=P, As, or Sb.

16. The memory cell of claim 8, wherein said Peltier strip comprises TiN.

17. The memory cell of claim 8, wherein said electrode having said negative thermopower characteristic comprises one of:
a half-Heusler alloy MNiSn, where M=Zn, Hf, or Ti; and
a cubic chalcogenide, having a composition AgPbₘSbTe₂₊ₘ.

18. The memory cell of claim 11, wherein said switching element comprises a field effect transistor (FET).

19. An apparatus, comprising:
a memory array, comprising:
a plurality of memory cells arranged in an array of rows and columns;
a word line for at least one said row, said word line connected to at least one memory cell in said row;
a bit line for at least one said column, said bit line connected to at least one memory cell in said column; and
a sense amplifier in each said bit line,
wherein at least one of said memory cells comprises:
a phase change material (PCM) element; and
a heating/cooling element external to said PCM element.

20. A method of increasing speed in a phase change material PCM random access memory (PRAM), said method comprising:
providing a cooling element to expedite a cooling process after said PCM material has been heated to change an information bit in a PRAM memory cell.

21. A method of forming a non-volatile memory cell, said method comprising:
forming a heating/cooling element on a substrate; and
forming a portion of phase change material (PCM) in close proximity to said heating/cooling element.

22. A memory cell, comprising:
a phase change material (PCM) element for storing bit information; and
a Peltier device located in a close proximity to a surface of said PCM element, said Peltier device serving selectively to heat said surface of said PCM element and to cool said surface of said PCM element,
wherein said information bit is stored in said PCM element within a PCM layer adjacent to said surface in close proximity to said Peltier device, a thickness of said PCM layer storing said information bit being in a nanoscopic range.
